(19) United States
(12) Patent Application Publication
(10) Pub. No.: US 2008/0007299 A1
(43) Pub. Date: Jan. 10, 2008

(54) Power generation circuit

(75) Inventor: Hijiri Shirasaki, Miyazaki (JP)

Correspondence Address: NIXON PEABODY, LLP, 401 9TH STREET, NW, SUITE 900, WASHINGTON, DC, 20004-2128, US

(73) Assignee: OKI ELECTRIC INDUSTRY CO., LTD.

(21) Appl. No.: 11/808,294

(22) Filed: Jun. 8, 2007

(30) Foreign Application Priority Data
Jul. 4, 2006 (JP) 2006-184000

(51) Int. Cl. H03K 19/0175

(52) U.S. Cl. 326/80

(57) ABSTRACT

In a power generation circuit configured by a voltage follower amplifier, a selector is provided inside of an operation amplifier. When a standby mode is released, a bias voltage in a constant current source is applied to a gate of a PMOS, and during a normal operation, an output voltage of a differential amplifier stage is applied to the gate of the PMOS. This favorably allows only the constant current to flow to a stable capacity after the standby mode is released, and prevents the flow of a large amount of current so that the power supply voltage is not dropped in value that much. The power generation circuit configured as such thus can prevent an inrush current from flowing to the stable capacity at startup without reducing the power supply efficiency and without complicating the circuit configuration.

### BACKGROUND OF THE INVENTION

1. Field of the Invention

The present invention relates to a power generation circuit using a voltage follower amplifier circuit (hereinafter, amplifier circuit referred to simply as “amplifier”) or others, and more specifically, to a technology against an inrush current at startup.

2. Description of the Related Art

FIG. 1 is a diagram showing the configuration of a general power generation circuit of conventional type.

The power generation circuit of FIG. 1 is configured to include a voltage follower amplifier 1 and a stable capacity 31. The voltage follower amplifier 1 is disposed on the side of various types of integrated circuit or device, and the stable capacity 31 is externally connected to a pad 30 being an external electrode provided to the device.

In the voltage follower amplifier 1, a positive (+) input terminal is connected to an input terminal IN, and a negative (−) input terminal is connected to an output terminal OUT. The input terminal IN is the one provided for receiving an input voltage Vin for reference use, and the output terminal OUT is for outputting an output voltage Vout. The output terminal OUT is connected to the pad 30. The voltage follower amplifier 1 is a circuit for supplying the power supply voltage Vout to the load of a circuit or others connected to the output terminal OUT. The voltage follower amplifier 1 is sometimes instantaneously put under a heavy load, i.e., current. Not to reduce the level of, i.e., level down, a power supply voltage VCC at such load application, the stable capacity 31 is thus externally connected.

In the voltage follower amplifier 1, the output voltage Vout coming from the output terminal OUT is always compared with the input voltage Vin provided to the input terminal IN. When the output voltage Vout is observed with any variation, this is fed back to the negative (−) input terminal so that the output voltage Vout is stabilized to the input voltage Vin.

FIG. 2 is a circuit diagram showing an exemplary configuration of the general previous voltage follower amplifier of FIG. 1.

This voltage follower amplifier 1 is configured to include a constant current source 10 and an operation amplifier 20. The operation amplifier 20 is connected to the output side of the constant current source 10.

The constant current source 10 is a circuit connected between a power supply terminal and a ground terminal. The power supply terminal receives the power supply voltage VCC, and is hereinafter referred to as “VCC terminal”. The ground terminal is retained at a ground voltage VSS (=0V), and is hereinafter referred to as “GND terminal”. When a control signal STBY at a logic level “H” is provided, and when an opposite-phase control signal STBYB at a logic level “L” is provided, the supply of the power supply voltage VCC is cut off so that the constant current source 10 stops operation. The opposite-phase control signal STBYB here is a signal opposite in phase to the first control signal STBY. If with the control signal STBY at the logic level “L”, and if with the opposite-phase signal STBYB at the logic level “H”, the supply of the power supply voltage VCC is started so that the constant current source 10 starts operating. The constant current source 10 generates a bias voltage VP of a constant level, and outputs a current of a constant level. The control signal STBY here is at the logic level “H” in a standby mode, and is changed to the logic level “L” when the standby mode is released.

The constant current source 10 is configured to include P-channel metal oxide semiconductor (MOS) transistors (hereinafter, referred to simply as “PMOSs”) 11 and 12, an N-channel MOS transistor (hereinafter, NMOSs 14 and 16. The PMOSs 11 and 12 are connected in parallel between the VCC terminal and nodes N13 and N14, and their gates are both connected to the node N13. The NMOS 13 and the resistance 15 are connected in series between the node N13 and the GND terminal. The NMOS 14 is connected between the node N14 and the GND terminal, and its gate is connected to the gate of the NMOS 13 and the node N14. The NMOS 16 is connected between the VCC terminal and the node N13, and is put under the gate control by the opposite-phase control signal STBYB. An NMOS 17 is connected between the node N14 and the GND terminal, and is put under the gate control by the control signal STBY.

The operation amplifier 20 is configured by a differential amplifier stage 21, and an output stage 22 connected to the output side of the differential amplifier stage 21.

The differential amplifier stage 21 is connected between the VCC terminal and the GND terminal. When a constant current comes from the constant current source 10, a voltage difference is amplified between the input voltage Vin provided to the input terminal IN and the output voltage Vout coming from the output terminal OUT. The voltage being an amplification result is output from a node N21c. The differential amplifier stage 21 is configured to include PMOSs 21a and 21b, and NMOSs 21c to 21e. The PMOSs 21a and 21b are connected in parallel between the VCC terminal and the node N21c and a node N21d, and their gates are both connected to the node N21d. The NMOS 21c is connected between the node N21c and a node N21e, and is put under the gate control by the input voltage Vin provided by the input terminal IN. The NMOS 21d is connected between the nodes N21d and N21e, and is put under the gate control by the output voltage Vout coming from the output terminal OUT. The NMOS 21e is connected between the node N21e and the GND terminal, and is put under the gate control by the voltage of the node N14 for use for the constant current source.

The output stage 22 is configured to include a PMOS 22a for use for an output transistor, and an NMOS 22b for use for the constant current source. The PMOS 22a is connected between the VCC terminal and the output terminal OUT, and is put under the gate control by the voltage coming from the node N21c of the differential amplifier stage 21. The NMOS 22b is connected between the output terminal OUT and the GND terminal, and is put under the gate control by the voltage of the node N14. Between the gate of the PMOS 22a and the output terminal OUT on the drain side, a phase compensation capacity 22c is connected.

In the voltage follower amplifier 1 configured as such in FIG. 2, described next is the operation A in a standby mode, and the operation B when the standby mode is released.

A. Operation in Standby Mode

The power supply voltage VCC is turned on, and when the control signal STBY is changed in level to “H” (“L” for the opposite-phase control signal STBYB), the mode goes into standby. In response, in the constant current source 10, the node N14 and the gates of the NMOSs 13 and 14 are reduced in voltage down to the ground voltage VSS (=0V). This is because the NMOS 16 is in the OFF state by the opposite-phase control signal STBYB being at “L”, and the NMOS 17 is in the ON state by the control signal STBY being at “H”. The NMOSs 13 and 14 are thus put in the OFF state, and the constant current source 10 is stopped operation. With the node N14 being at 0V, the NMOSs 21e and 22b are both put in the OFF state in the operation amplifier 20, and the operation amplifier 20 is thus stopped operation.

B. Operation after Standby Mode is Released

The initial values are assumed as being 0V both for the output voltage Vout of the operation amplifier 20, and the terminal voltage of the stable capacity 31 connected to the output terminal OUT.

The control signal STBY is changed in level to “L” (“H” for the opposite-phase control signal STBYB), and the standby mode is released. In response, in the constant current source 10, the NMOS 16 is put in the ON state, and the NMOS 17 is put in the OFF state, and in the operation amplifier 20, the NMOSs 21e and 22b are both put in the ON state so that the constant current source 10 and the operation amplifier 20 both start operating. In response thereto, a drain/source current of a constant level flows to the NMOSs 13 and 14 in the constant current source 10. The drain/source current of a constant level flows also to the NMOSs 21e and 22b in the operation amplifier 20, which configures a current mirror circuit together with the NMOSs 13 and 14.

The voltage of the output terminal OUT of the operation amplifier 20 starts going up from 0V to any desired level, i.e., the level of the input voltage Vin of the input terminal IN. At the same time, the output terminal OUT puts the stable capacity 31 on charge. At this time, the PMOS 22a for use for the output transistor is put in the ON state because the gate voltage is reduced, and the current starts flowing from the VCC terminal toward the stable capacity 31 via the output terminal OUT so that the voltage is increased. When the output voltage Vout comes closer in level to the input voltage Vin, the gate voltage of the PMOS 22a starts going up by degrees, and the PMOS 22a is put in the OFF state. The current supply is thus stopped from the VCC terminal.

The technology related to such a power generation circuit is described in Japanese Patent Kokai No. 2005-184904 (Patent Document 1), for example.

Patent Document 1 describes a technology about electrical equipment in which a power supply voltage of a USB (Universal Serial Bus) host device is provided to both the internal circuit, and any external USB device. The USB host device includes therein a power generation circuit, and the external USB device is connected via a USB connector.

### SUMMARY OF THE INVENTION

Such previous power generation circuit of FIGS. 1 and 2 has problems of a and b as follows.

a. In the voltage follower amplifier 1 of FIG. 2, when the externally-connected stable capacity 31 is put on charge after a standby mode is released, a large amount of current flows from the VCC terminal to the stable capacity 31. This is because the PMOS 22a is put in the ON state due to its low gate voltage. In the actual device, because the wiring resistance exists in the VCC terminal, the large amount of current may reduce the level of the power supply voltage VCC, thereby causing malfunction to a load circuit that is also receiving the power supply voltage VCC in the device. As such, there needs to take measures against a large amount of current not to flow at the instant when a standby mode is released.

As possible measures, for example, the PMOS 22a may be increased in impedance, i.e., ON-resistance value in the ON state, to reduce the current value, or the stable capacity 31 may be reduced in size to reduce the incoming amount of current. Such measures are ideally expected to make a power generation circuit have, in terms of output, a power supply efficiency of resisting a heavy load, i.e., instantaneous large amount of current. In real world, however, if the PMOS 22a has a large ON-resistance value, it takes time for the output voltage Vout to return in value after the value drop due to the heavy load. On the other hand, if the stable capacity 31 is small in size, the value drop of the power supply voltage VCC is increased. The load circuit thus suffers from voltage reduction because the power source of which is the power supply voltage VCC. The load circuit may be thus put out of operation thereby.

b. In order to solve the problem of a, the technology of Patent Document 1 may be utilized.

Patent Document 1 describes the technology of providing an inrush current safety circuit to a USB host device including a power generation circuit. The safety circuit serves to prevent an inrush current from flowing from the USB host device to any external USB device of some capacity at the instant when a connection is established between the USB host device and the external USB device via a USB connector. In the inrush current safety circuit, an output MOS transistor is provided on the output side of the power generation circuit. When a power supply voltage is directed from the output MOS transistor to the USB device, the output MOS transistor is subjected to ON/OFF control by varying the gate voltage so that the inrush current is reduced.

There is a problem, however, if such a technology of Patent Document 1 about the MOS transistor is applied to the voltage follower amplifier 1 of FIG. 2, e.g., the output MOS transistor is provided as an alternative to the PMOS 22a of FIG. 2. That is, as is subjected to ON/OFF control based on the value of the gate voltage, the output MOS transistor is not fully capable of outputting a variable current as the PMOS 22a. To make the output MOS transistor capable of outputting a variable current like the PMOS 22a, the operation amplifier 20 has to be changed in circuit configuration to a considerable degree. As such, it has been difficult to implement, with a relatively simple circuit configuration, a power generation circuit that can stop, without fail, the flowing of the inrush current as generated in FIG. 2.

A power generation circuit of the invention includes a constant current source, a differential amplifier stage, an output transistor, and a control device.

The constant current source is connected to a power supply terminal that receives a power supply voltage. Under a control of a first control signal that is at a first logic level in a standby mode and is changed to a second logic level when the standby mode is released, when the first logic level is provided, the constant current source stops operation as a supply of the power supply voltage is cut off. When the second logic level is provided, the constant current source starts operating as the supply of the power supply voltage comes, and generates a constant bias voltage and outputs a constant current. The differential amplifier stage is connected to the power supply terminal. The differential amplifier stage amplifies, when the constant current is provided, a difference between an input voltage and the voltage of an output terminal connected with a stable capacity, and outputs a resulting amplified voltage.

The output transistor is connected between the power supply terminal and the output terminal, and flows a power supply current to the output terminal with control exercised over continuity based on the voltage of a control node. The control device is under a control of a second control signal that is at a third logic level when the standby mode is released and is changed to a fourth logic level after a predetermined length of time passes. When the third logic level is provided, the control device applies, to the control node, a predetermined voltage that increases an ON-resistance value when the output transistor is put in continuity. When the fourth logic level is provided, the control device applies the output voltage of the differential amplifier stage to the control node.

According to the invention, the control device applies, to the control node, the predetermined voltage or the output voltage of the differential amplifier stage. With this configuration, the ON-resistance value of the output transistor is controlled by the predetermined voltage that is applied to the control node only when the standby mode is released. This accordingly adjusts the amount of current flowing to the stable capacity so that no large amount of current flows at startup. Such a configuration can be implemented without reducing the power supply efficiency and without complicating the circuit configuration.

### BRIEF DESCRIPTION OF THE DRAWINGS

FIG. 1 is a diagram showing the configuration of a general power generation circuit of conventional type;

FIG. 2 is a circuit diagram showing an exemplary configuration of a previous voltage follower amplifier of FIG. 1;

FIG. 3 is a circuit diagram showing an exemplary configuration of a power generation circuit in a first embodiment of the invention;

FIG. 4 is a timing chart of the operation of the voltage follower amplifier of FIG. 3; and

FIG. 5 is a circuit diagram showing an exemplary configuration of a power generation circuit in a second embodiment of the invention.

### DETAILED DESCRIPTION OF THE INVENTION

A power generation circuit is configured to include a constant current source, a differential amplifier stage, an output transistor, and control device, e.g., selection circuit.

The constant current source is a circuit connected to a power supply terminal that receives a power supply voltage. Under a control of a first control signal that is at a first logic level, e.g., “H”, in a standby mode and is changed to a second logic level, e.g., “L”, when the standby mode is released, when the first logic level is provided, the constant current source stops operation as a supply of the power supply voltage is cut off. When the second logic level is provided, the constant current source starts operating as the supply of the power supply voltage comes, and generates a constant bias voltage and outputs a constant current.

The differential amplifier stage is a circuit connected to the power supply terminal. When the constant current is provided, the differential amplifier stage amplifies a difference between an input voltage and the voltage of an output terminal connected with a stable capacity, and outputs the resulting amplified voltage. The output transistor is connected between the power supply terminal and the output terminal, and flows a power supply current to the power supply terminal with control exercised over continuity based on the voltage of a control node.

The selection circuit selects, when receiving the bias voltage and the output voltage of the differential amplifier stage, and when receiving the third logic level of the second control signal, the bias voltage as the predetermined voltage for application to the control node. When receiving the fourth logic level of the second control signal, the selection circuit selects the output voltage of the differential amplifier stage for application to the control node.

### First Embodiment

### Configuration in First Embodiment

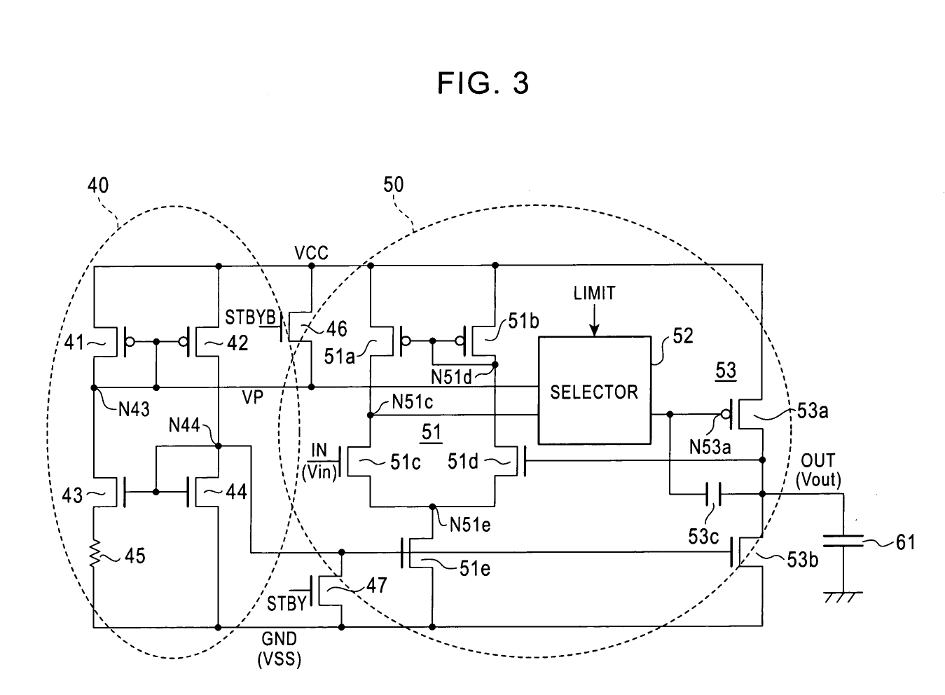

FIG. 3 is a circuit diagram showing an exemplary configuration of a power generation circuit in a first embodiment of the invention.

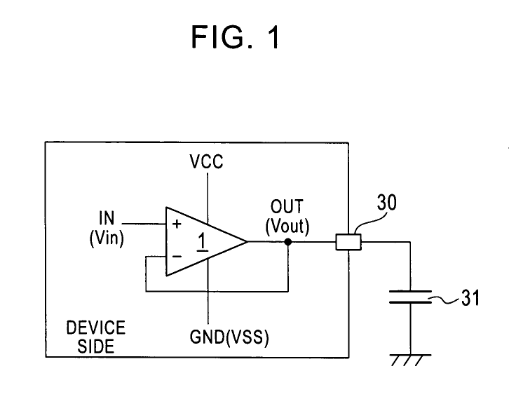

Similarly to the previous power generation circuit of FIG. 1, the power generation circuit is configured to include a voltage follower amplifier provided on the device side, and a stable capacity 61 that is externally connected to a pad provided on the device side.

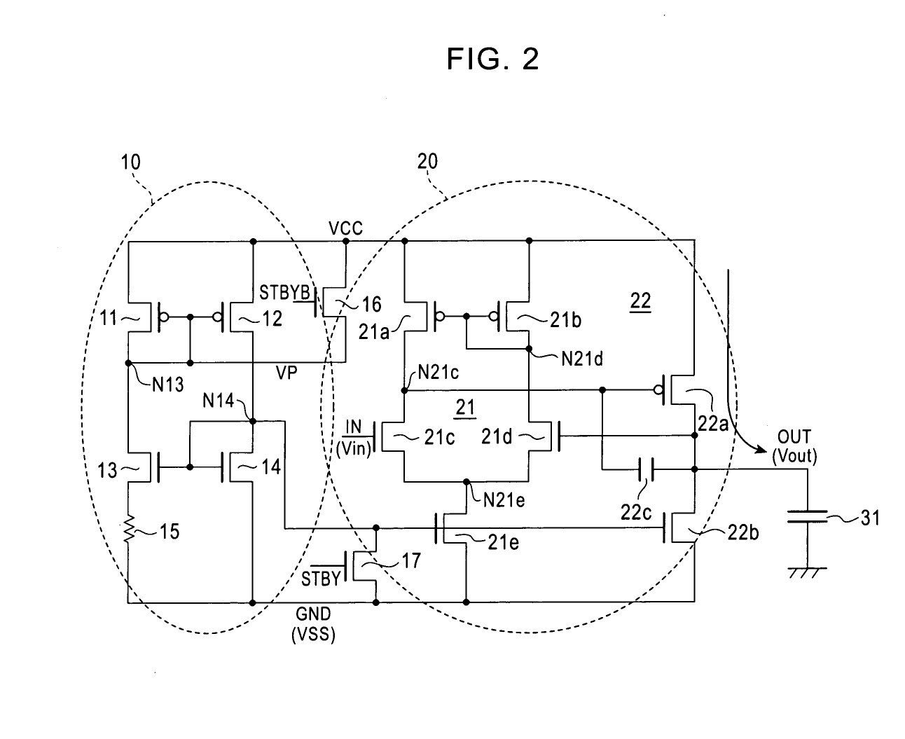

The voltage follower amplifier in the first embodiment is configured to include a constant current source 40, and an operation amplifier 50 connected to the output side of the constant current source 40. The constant current source 40 is similar to that of FIG. 2, and the operation amplifier 50 is configured differently from the previous operation amplifier 20.

The constant current source 40 is a circuit connected between a VCC terminal receiving a power supply voltage VCC, and a GND terminal retained at a ground voltage VSS (=0V). When a first control signal STBY at a first logic level “H” is provided, and when an opposite-phase control signal STBYB at a first logic level “L” is provided, the supply of the power supply voltage VCC is cut off so that the constant current source 40 stops operation. The opposite-phase control signal STBYB here is a signal opposite in phase to the first control signal STBY. If with the control signal STBY at a second logic level “L”, and if with the opposite-phase signal STBYB at a second logic level “H”, the supply of the power supply voltage VCC is started so that the constant current source 40 starts operating. The constant current source 40 generates a bias voltage VP of a predetermined level, e.g., voltage of a level in the vicinity of (VCC−Vtp) where Vtp denotes a threshold voltage of a PMOS 53a), and outputs a current of a constant level. The control signal STBY here is at the first logic level “H” in a standby mode, and is changed to the second logic level “L” when the standby mode is released.

The constant current source 40 is configured by PMOSs 41 and 42, an NMOS 43 and a resistance 45, an NMOS 44, and NMOSs 46 and 47. The PMOS 41 is the one provided for a generation source of the bias voltage VP, in which a source electrode (hereinafter, simply source)/drain electrode (hereinafter, simply drain) is connected to the VCC terminal and a node N43, and a gate electrode (hereinafter, simply gate) is connected to the node N43. In the PMOS 42, a source/drain is connected to the VCC terminal and a node N44, and a gate is connected to the gate of the PMOS 41. The NMOS 43 and the resistance 45 are connected in series between the node N43 and the GND terminal. In the NMOS 44, a drain/source is connected to the node N44 and the GND terminal, and a gate is connected to a gate of the NMOS 43 and the node N44. In the NMOS 46, a drain/source is connected to the VCC terminal and the node N43, and a gate is controlled by the opposite-phase control signal STBYB. In the NMOS 47, a drain/source is connected to the node N44 and the GND terminal, and a gate is controlled by the control signal STBY.

The operation amplifier 50 is configured to include a differential amplifier stage 51, control means, e.g., selector being a selection circuit, 52 for control use over an output transistor, and an output stage 53. In the configuration of the first embodiment, the basic difference from that of FIG. 2 is that the selector 52 is additionally provided.

The differential amplifier stage 51 is connected between the VCC terminal and the GND terminal. When a constant current comes from the constant current source 40, the differential amplifier stage 51 amplifies a difference between an input voltage Vin provided to an input terminal IN and an output voltage Vout coming from an output terminal OUT. The voltage being an amplification result is output from a node N51c.

The differential amplifier stage 51 is configured to include PMOSs 51a and 51b, and NMOSs 51c to 51e. In the PMOS 51a, a source/drain is connected to the VCC terminal and the node 51c. In the PMOS 51b, a source/drain is connected to the VCC terminal and a node N51d, and a gate is connected to the PMOS 51a and the node N51d. In the NMOS 51c, a drain/source is connected to the node N51c and a node N51e, and a gate is controlled by the input voltage Vin coming from the input terminal IN. In the NMOS 51d, a drain/source is connected to the nodes N51d and N51e, and a gate is controlled by the control voltage Vout coming from the output terminal OUT. The NMOS 51e is provided for use for the constant current source, in which a drain/source is connected to the node N51e and the GND terminal, and a gate is controlled by the voltage of the node N44.

The selector 52 is a circuit including two input terminals and one output terminal. In the selector 52, one of the two input terminals is connected to the node N43 outputting the bias voltage VP, and the other input terminal is connected to the node N51c outputting the output voltage of the differential amplifier stage 51. The output terminal is connected to a control node N53a. When a third logic level, e.g., “H”, of a second control signal Limit is provided, the bias voltage VP is selected as a predetermined voltage for application to the control node N53a, and when a fourth logic level, e.g., “L”, of the second control signal Limit is provided, the output voltage of the differential amplifier stage 51 is selected for application to the control node N53a. The selector 52 is configured by a switch element such as PMOS, for example.

The output stage 53 is configured by an output transistor, e.g., PMOS, 53a, and an NMOS 53b for use for the constant current use. In the PMOS 53a, a source/drain is connected to the VCC terminal and the output terminal OUT, and a gate is controlled by the voltage of the control node N53a. In the NMOS 53b, a drain/source is connected to the output terminal OUT and the GND terminal, and a gate is controlled by the voltage of the node 44. Between the gate of the PMOS 53a and the output terminal OUT on the drain side, a phase compensation capacity 53c is connected.

The NMOSs 43, 44, 51e, 53b for use for the constant current source configure a current mirror circuit. The control signal Limit provided to the selector 52 is at a logic level “H” for a time T until the output voltage Vout of the operation amplifier 50 becomes stable after a standby mode is released. The time T is a value set in advance based on a CR time constant between an ON-resistance value R of the PMOS 53a and a value C of the external stable capacity 61. In the state that the bias voltage VP of the node N43 is selected by the selector 52, and the bias voltage VP is applied to the gate of the PMOS 53a on the side of the control node N53a, the PMOS 41 for a generation source of the bias voltage VP and the PMOS 53a configure a current mirror circuit.

### Operation in First Embodiment

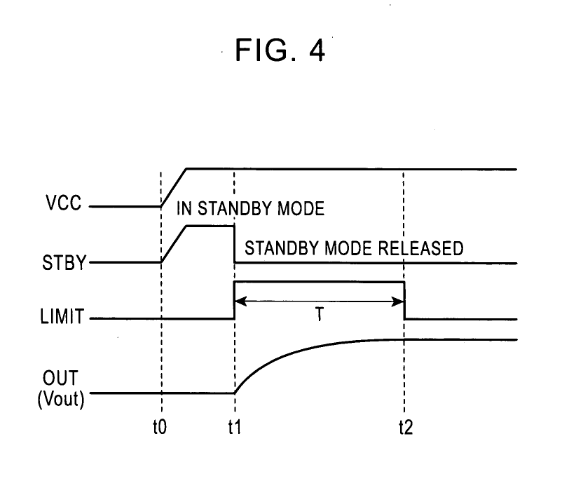

FIG. 4 is a timing chart of the operation of the voltage follower amplifier of FIG. 3.

Described below is an operation A in a standby mode, and an operation B after the standby mode is released.

A. Operation in Standby Mode

At a time t0, the power supply voltage VCC is turned on (“H”), and when the control signal STBY is changed in level to “H” (“L” for the opposite-phase control signal STBYB), the mode goes into standby. In response, in the constant current source 40, the node N44 and the gates of the NMOSs 43 and 44 are reduced in voltage down to the ground voltage VSS (=0V). This is because the NMOS 46 is in the OFF state by the opposite-phase control signal STBYB being at “L”, and the NMOS 47 is in the ON state by the control signal STBY being at “H”. The NMOSs 43 and 44 are thus put in the OFF state, and the constant current source 40 is stopped operation so that no power supply current flows to the constant current source 40. With the node N44 being at 0V, the NMOSs 51e and 53b are both put in the OFF state in the operation amplifier 50. The operation amplifier 50 is thus stopped operation, and no power supply current flows thereto.

B. Operation after Standby Mode is Released

The initial values are assumed as being 0V both for the output voltage Vout of the operation amplifier 50, and the terminal voltage of the stable capacity 61 connected to the output terminal OUT.

At the time t1, the control signal STBY is changed in level to “L” (“H” for the opposite-phase control signal STBYB), and the control signal Limit is changed in level to “H” to release the standby mode. In response, in the constant current source 40, the NMOS 46 is put in the ON state, and the NMOS 47 is put in the OFF state, and in the operation amplifier 50, the NMOSs 51e and 53b are both put in the ON state. By the control signal Limit being changed in level to “H”, the selector 52 selects the voltage of the node N43, and puts it into the state ready for application to the control node N53a.

The constant current source 40 and the operation amplifier 50 both start operating by the ON state of the NMOS 46, the OFF state of the NMOS 47, and the ON states of the NMOSs 51e and 53b. In response, a drain/source current of a constant level starts flowing to the NMOSs 43 and 44 in the constant current source 40. The bias voltage VP, e.g., voltage of a level in the vicinity of (VCC−Vtp), is generated to the node N43. This bias voltage VP is selected by the selector 52 for application to the control node N53a. The drain/source current of a constant level flows also to the NMOSs 51e and 53b in the operation amplifier 50, which configure a current mirror circuit together with the NMOSs 43 and 44.

The voltage of the output terminal OUT of the operation amplifier 20 starts going up from 0V to any desired level, i.e., the level of the input voltage Vin of the input terminal IN. At the same time, the output terminal OUT puts the stable capacity 61 on charge. At this time, the gate of the PMOS 53a for use for the output transistor is biased by the voltage of a level in the vicinity of (VCC−Vtp) (where Vtp denotes the threshold voltage of the PMOS 53a), and the PMOS 53a is put in semicontinuity. This is because the control node N53a is being applied with the bias voltage VP. The current then starts flowing from the VCC terminal toward the stable capacity 61 via the PMOS 53a and the output terminal OUT so that the voltage goes up.

After the standby mode is released, when a time t2 comes after the passage of time T needed for the output voltage Vout of the output terminal OUT to be stabilized, the control signal Limit is changed in level to “L”, and the selector 52 selects the output voltage of the differential amplifier stage 50 provided by the node N51c. Thus selected output voltage is applied to the gate of the PMOS 53a via the control node N53a. This accordingly puts the PMOS 53a in the full ON state. When the output voltage Vout comes closer in level to the input voltage Vin, the gate voltage of the PMOS 53a, i.e., the output voltage of the differential amplifier stage 50, starts going up by degrees. The PMOS 53a is then put in the OFF state, and the current supply from the VCC terminal is stopped.

Note that, after the time t2 in the normal operation, the control signal Limit is not operated, and no process is executed to operate again the control signal Limit when the output voltage Vout is dropped in value.

### Effect of First Embodiment

In the first embodiment, the following effects of 1 and 2 can be achieved.

1. The selector 52 is provided to limit a current flowing to the PMOS 53a only at the moment when the standby mode is released, and such a current limitation is removed thereafter in the normal operation when the output voltage Vout is stable. As such, in the configuration of the first embodiment, the bias voltage VP is applied to the gate of the PMOS 53a when the standby mode is released, and the output voltage of the differential amplifier stage 50 is applied to the gate of the PMOS 53a in the normal operation. After the standby mode is released, the bias voltage VP is applied to the gate of the PMOS 53a so that the gate is biased by the voltage of a level in the vicinity of (VCC−Vtp). This prevents the PMOS 53a being put in the full ON state so that the source-drain ON resistance value can be increased for the PMOS 53a, and the drain current can remain low.

As such, after the standby mode is released, the current flowing to the stable capacity 61 is limited to be constant in level, and no current of large amount is allowed to flow thereto so that the power supply voltage VCC is prevented from dropping in value. What is better, this is implemented without reducing the power supply efficiency and without complicating the circuit configuration.

2. The amount of a current flowing to the PMOS 53a is determined by a ratio of channel width to channel length (W/L) between the PMOS 41 for a generation source of the bias voltage VP and the PMOS 53a, which configures a current mirror circuit. The amount of current can be thus also adjusted.

### Second Embodiment

### Configuration in Second Embodiment

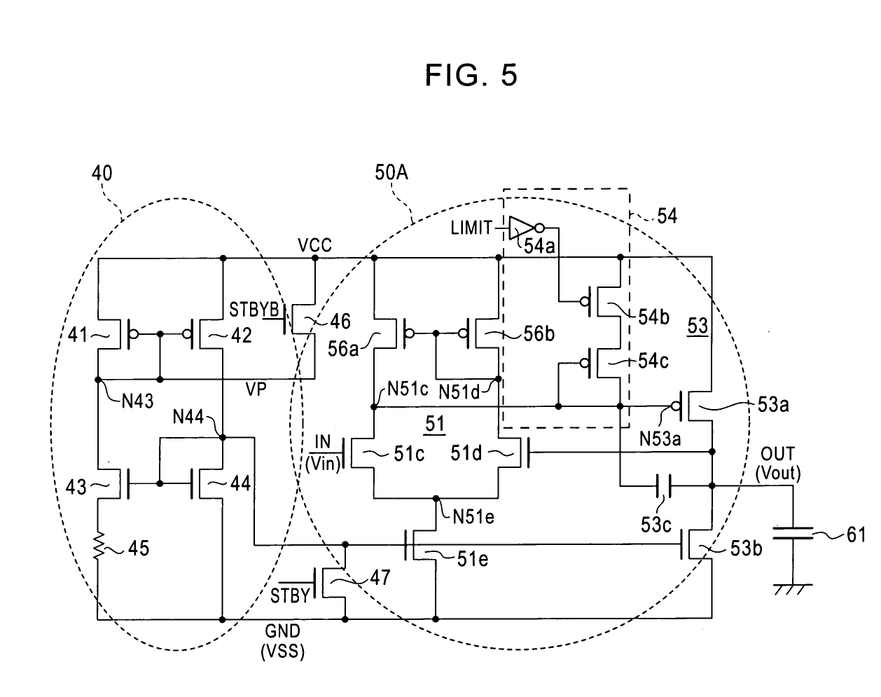

FIG. 5 is a circuit diagram showing an exemplary configuration of a power generation circuit in a second embodiment of the invention. Any component similar to that of the first embodiment in FIG. 3 is provided with the same reference numeral.

In the first embodiment, the selector 52 is disposed on the gate input side of the PMOS 53a. This selector 52 is configured by a switch element such as PMOS, and there is a resistance between the output node N51c of the differential amplifier stage 50 and the gate-side control node N53a of the PMOS 53a. This configuration reduces the response of the voltage follower amplifier, and there is a concern about the possible value drop of the output voltage Vout with respect to the load current under the normal operation.

For betterment, in the second embodiment, an operation amplifier 50A is provided as an alternative to the operation amplifier 50 including the selector 52 being the control means. The operation amplifier 50A is configured differently from the operation amplifier 50. In this operation amplifier 50A, as an alternative to the selector 52 in the first embodiment, a constant current transistor circuit 54 being the control means is provided.

The constant current transistor circuit 54 is connected between the VCC terminal and the control node N53a. When the third logic level, e.g., “H”, of the second control signal Limit comes, the constant current transistor circuit 54 is put in the ON state, and supplies a constant current to the control node N53a. The constant current transistor circuit 54 then biases the control node N53a to a predetermined voltage, e.g., a voltage of a level in the vicinity of (VCC−Vtp). When the fourth logic level, e.g., “L”, of the second control signal Limit comes, the constant current transistor circuit 54 is put in the OFF state, and applies the output voltage of the differential amplifier stage 51 to the control node N53a.

The constant current transistor circuit 54 is configured to include an inverter 54a, a first transistor, e.g., PMOS, 54b, and a second transistor, e.g., PMOS, 54c. The inverter 54a serves to invert the control signal Limit. The PMOS 54b is controlled over the continuity by the resulting inversion signal, and the PMOS 54c is provided for use for the constant current source, and is controlled by, over continuity, the voltage on a signal line between the output node N51c of the differential amplifier stage 51 and the control node N53a. These PMOSs 54b and 54c are connected in series between the VCC terminal and the signal line. The remaining configuration is similar to that of the first embodiment.

### Operation in Second Embodiment

In the second embodiment, as shown in FIG. 4, after the standby mode is released at the time t1, the PMOS 54b and the PMOS 54c for the constant current source are both put in the ON state by the control signal Limit being at “H”. The gate voltage of the PMOS 53a of the operation amplifier 50A is biased to the voltage of a level in the vicinity of (VCC−Vtp) by the PMOS 54c for the constant current source so that the PMOS 53a is not put in the full ON state. Thereafter, in the normal operation at the time t2, the PMOS 54b and the PMOS 54c for the constant current source are both put in the OFF state by the control signal Limit being at “L”, and the output voltage of the differential amplifier stage 51 is provided to the gate of the PMOS 53a. As such, the operation is similar to that in the first embodiment.

### Effect of Second Embodiment

In the second embodiment, in a manner substantially the same as the first embodiment, the current of the PMOS 53a is so controlled as to be constant in level after the standby mode is released so that no current of large amount is allowed to flow. What is better, the amount of the current is determined by a ratio of channel width to channel length (W/L) of the PMOS 54c for the constant current source so that the amount of current can be adjusted.

### MODIFIED EXAMPLE

The invention is not restrictive to the first and second embodiments described above, and numerous other modifications and variations can be devised as below, e.g., a to c.

a. In FIGS. 3 and 5, the NMOSs and PMOSs configuring the power generation circuit may be switched through polarity change of a power supply, e.g., NMOSs are changed to PMOSs or PMOSs to NMOSs, or these MOS transistors may be configured by other types of transistor, e.g., bipolar transistor.

b. Described in the first and second embodiments is the power generation circuit configured by a voltage follower amplifier. Alternatively, an inverted differential amplifier is also an option, i.e., gain is changed using resistance.

c. The configuration of the first embodiment is applicable to take measures against an inrush current in a power generation circuit such as a charge pump booster circuit. For use in the charge pump voltage booster circuit, for example, a transistor for use as a switch for voltage increase may be controlled by two voltage levels via the selector 52, and only at startup, the transistor showing the high resistance value may be controlled so that the inrush current can be taken care of.

This application is based on Japanese Patent Application No. 2006-184000 which is hereby incorporated by reference.

What is claimed is:

1. A power generation circuit, comprising:
a constant current source stopping, with a connection to a power supply terminal receiving a power supply voltage, under a control of a first control signal that is at a first logic level in a standby mode and is changed to a second logic level when the standby mode is released, operation as a supply of the power supply voltage is cut off when the first logic level is provided, starting operation as the supply of the power supply voltage comes when the second logic level is provided, and generating a constant bias voltage and outputting a constant current;
a differential amplifier stage amplifying, with a connection to the power supply terminal, when the constant current is provided, a difference between an input voltage and a voltage of an output terminal connected with a stable capacity, and outputting a resulting amplified voltage;
an output transistor flowing, with a connection between the power supply terminal and the output terminal, a power supply current to the output terminal with control exercised over continuity based on a voltage of a control node; and
a control device which applies, to the control node, under a control of a second control signal that is at a third logic level when the standby mode is released and is changed to a fourth logic level after a predetermined length of time passes, a predetermined voltage that increases an ON-resistance value when the output transistor is put in continuity when the third logic level is provided, and applies the output voltage of the differential amplifier stage to the control node when the fourth logic level is provided.

2. The power generation circuit according to claim 1, wherein
the control device is configured by a selection circuit that receives the bias voltage and the output voltage of the differential amplifier stage, and when the third logic level of the second control signal is provided, selects the bias voltage as the predetermined voltage for application to the control node, and when the fourth logic level of the second control signal is provided, selects the output voltage of the differential amplifier stage for application to the control-node.

3. The power generation circuit according to claim 2, wherein
the selection circuit is configured by a transistor selector that receives the bias voltage and the output voltage of the differential amplifier stage, and based on the second control signal, selects either the bias voltage or the output voltage of the differential amplifier stage for output to the control node.

4. The power generation circuit according to claim 1, wherein
the control device is configured by a constant current transistor circuit that is connected between the power supply terminal and the control node, and when the third logic level of the second control signal is provided, is put in an ON state and supplies a constant current to the control node for biasing the control node to the predetermined voltage, and when the fourth logic level of the second control signal is provided, is put in an OFF state and applies the output voltage of the differential amplifier stage to the control node.

5. The power generation circuit according to claim 4, wherein
the constant current transistor circuit includes a first transistor under a control of the second control signal over continuity, and a second transistor under a control, over continuity, for use for the constant current source, of a voltage on a signal line connecting the output terminal of the differential amplifier stage and the control node, and
the first and second transistors are connected in series between the power supply terminal and the signal line.

6. The power generation circuit according to claim 1, wherein
the output transistor is a MOS transistor in which a source electrode and a drain electrode are connected between the power supply terminal and the output terminal, and a gate electrode is connected to the control node.

7. The power generation circuit according to claim 6, wherein
the predetermined voltage has a value in a vicinity of (VCC−Vt) (where VCC denotes the power supply voltage, and Vt denotes a threshold voltage of the MOS transistor).

8. The power generation circuit according to claim 1 wherein
the constant current source, the differential amplifier stage, and the output transistor are configured by a voltage follower amplifier circuit.

9. A power generation circuit, comprising:
a constant current source stopping, with a connection to a power supply terminal receiving a power supply voltage, under a control of a first control signal that is at a first logic level in a standby mode and is changed to a second logic level when the standby mode is released, operation as a supply of the power supply voltage is cut off when the first logic level is provided, starting operation as the supply of the power supply voltage comes when the second logic level is provided, and generating a constant bias voltage and outputting a constant current;
a differential amplifier stage amplifying, with a connection to the power supply terminal, when the constant current is provided, a difference between an input voltage and a voltage of an output terminal connected with a stable capacity, and outputting a resulting amplified voltage;
an output transistor flowing, with a connection between the power supply terminal and the output terminal, a power supply current to the output terminal with control exercised over continuity based on a voltage of a control node; and
control means for applying, to the control node, under a control of a second control signal that is at a third logic level when the standby mode is released and is changed to a fourth logic level after a predetermined length of time passes, a predetermined voltage that increases an ON-resistance value when the output transistor is put in continuity when the third logic level is provided, and applying the output voltage of the differential amplifier stage to the control node when the fourth logic level is provided.

10. The power generation circuit according to claim 9, wherein
the control means is configured by a selection circuit that receives the bias voltage and the output voltage of the differential amplifier stage, and when the third logic level of the second control signal is provided, selects the bias voltage as the predetermined voltage for application to the control node, and when the fourth logic level of the second control signal is provided, selects the output voltage of the differential amplifier stage for application to the control node.

11. The power generation circuit according to claim 10, wherein
the selection circuit is configured by a transistor selector that receives the bias voltage and the output voltage of the differential amplifier stage, and based on the second control signal, selects either the bias voltage or the output voltage of the differential amplifier stage for output to the control node.

12. The power generation circuit according to claim 9, wherein
the control means is configured by a constant current transistor circuit that is connected between the power supply terminal and the control node, and when the third logic level of the second control signal is provided, is put in an ON state and supplies a constant current to the control node for biasing the control node to the predetermined voltage, and when the fourth logic level of the second control signal is provided, is put in an OFF state and applies the output voltage of the differential amplifier stage to the control node.

13. The power generation circuit according to claim 12, wherein
the constant current transistor circuit includes a first transistor under a control of the second control signal over continuity, and a second transistor under a control, over continuity, for use for the constant current source, of a voltage on a signal line connecting the output terminal of the differential amplifier stage and the control node, and
the first and second transistors are connected in series between the power supply terminal and the signal line.

14. The power generation circuit according to claim 9, wherein
the output transistor is a MOS transistor in which a source electrode and a drain electrode are connected between the power supply terminal and the output terminal, and a gate electrode is connected to the control node.

15. The power generation circuit according to claim 14, wherein
the predetermined voltage has a value in a vicinity of (VCC−Vt) (where VCC denotes the power supply voltage, and Vt denotes a threshold voltage of the MOS transistor).

16. The power generation circuit according to claim 9 wherein
the constant current source, the differential amplifier stage, and the output transistor are configured by a voltage follower amplifier circuit.
